(19) United States
(12) Patent Application Publication
(10) Pub. No.: US 2025/0370031 A1
(43) Pub. Date: Dec. 4, 2025

(54) INDIVIDUALIZED IDENTIFIER FOR INTEGRATED CIRCUIT CHIPS

(71) Applicant: Analog Devices International Unlimited Company, Limerick (IE)

(72) Inventors: Michael C.W. Coln, Lexington, MA (US); Ramji Sitaraman Lakshmanan, Limerick (IE); Roman Trogan, Needham, MA (US); Aditya Yadav, Boston, MA (US)

(21) Appl. No.: 18/680,908

(22) Filed: May 31, 2024

(51) Int. Cl. G01R 31/28; G01R 1/20; G01R 27/26

(52) U.S. Cl. CPC G01R 31/2851; G01R 1/203; G01R 27/2605

(57) ABSTRACT

This disclosure relates to a method of traceability for integrated circuit chips. The method includes measuring a circuit parameter of multiple integrated circuit elements of an integrated circuit chip of interest to produce an individualized identifier for the integrated circuit chip of interest using multiple measurements of the circuit parameter; comparing the individualized identifier to an identifier database including identifiers of multiple integrated circuit chips; and identifying the integrated circuit chip of interest as a specific integrated circuit chip of the identifier database using the comparison of the individualized identifier to the identifier database.

### FIELD OF THE DISCLOSURE

This document relates to integrated circuits. Some embodiments relate to circuit topologies that produce an individualized identifier for an integrated circuit chip.

### BACKGROUND

In many semiconductor integrated circuit chip applications, it may be desirable to be able to trace individual integrated circuit chips. For example, operating parameters of the integrated circuit chips may slightly vary from one chip to another, so that during manufacture these parameters can be measured, stored, and subsequently used for calibration during operation in the field. With individualized identification available, it becomes possible to look-up the proper calibration data for each device. In another example, if some chips are found to exhibit degraded performance or failures post-manufacture, it may be useful to determine their manufacturing history to localize the root-cause of the issue.

### SUMMARY OF THE DISCLOSURE

This document relates generally to circuit topologies used to produce unique individualized identifiers for integrated circuit chips. These individualized identifiers can be viewed as a unique “fingerprint” for identifying an individual chip from other chips that may have fabricated in the same or different manufacturing lots. The individualized identifier enables traceability of the specific integrated circuit chip throughout the lifetime of the chip.

In some embodiments, a method of identifying an integrated circuit chip includes measuring a circuit parameter of multiple integrated circuit elements of an integrated circuit chip of interest to produce an individualized identifier for the integrated circuit chip of interest using multiple measurements of the circuit parameter, comparing the individualized identifier to an identifier database including identifiers of multiple integrated circuit chips, and identifying the integrated circuit chip of interest as a specific integrated circuit chip of the identifier database using the comparison of the individualized identifier to the identifier database.

In some embodiments, an integrated circuit includes multiple circuit elements, an analog-to-digital converter (ADC) circuit, and logic circuitry. The logic circuitry is configured to produce, using the ADC circuit, digital values representative of a circuit parameter of the multiple integrated circuit elements, and output an individualized identifier of the integrated circuit chip that includes the produced digital values.

This section is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 is a flow diagram of an example of a method of identifying integrated circuit chips.

FIG. 2 is a block diagram of an integrated circuit chip and an electronic device.

FIG. 3 is a circuit diagram of an example of a measurement circuit to measure circuit parameters of circuit elements of an integrated circuit chip.

FIG. 4 is a circuit diagram of another example of a measurement circuit to measure circuit parameters of circuit elements of an integrated circuit chip.

### DETAILED DESCRIPTION

Electronic devices can include semiconductor integrated circuit chips. The integrated circuit chips are fabricated simultaneously as adjoining dice on semiconductor wafers. Multiple wafers of the integrated circuits can be processed together as a boat of wafers. The dice of the fabricated wafers are then sawn from the wafers and then packaged. As explained previously herein there are reasons why traceability of individual integrated circuit chips is desirable. However, because many dice are fabricated at a time it becomes difficult to identify individual integrated circuit chips.

One approach to tracking integrated circuit chips involves well-managed handling of the individual dice as they are sawn from wafers and packaged, and laser-scribing of the dice with alpha-numeric data on the package. Depending on the packaging, it is then necessary to optically read the data to recover the identification. Another approach would be to include the capability in the chips to electrically read out chip identification using the existing electrical interface of the chip. Some chips incorporate non-volatile memory capability on the chip, so that the identifying information can be programmed during manufacture and later read out to identify the chip. However, non-volatile memory is not always included in integrated circuit ships and such an approach is not always an option.

Despite the simultaneous fabrication of the integrated circuit chips, there are inherent manufacturing variations from one chip to the next despite the efforts to minimize such variations. These inherent manufacturing variations can be captured at time of manufacturing and subsequently used to uniquely identify individual integrated chips. The manufacturing variations may be manifest as variations in a parameter of a circuit element of the integrated circuit chips. By quantizing and reading out the variations using an external interface of integrated circuit chip, the captured variations can serve as an electronic fingerprint to identify the chip. These chip-to-chip variations arise from random manufacturing effects and are not deterministic. Because the variations are unpredictable and uncontrollable, capturing and recording the variations results in an identifier that individually identifies an integrated circuit chip.

To produce an identifier, multiple circuit elements (e.g., tens to hundreds) intended to be identical are fabricated on the chip. The circuit parameters of the circuit elements are measured and read out from the integrated circuit chip using an external interface. The read out file of measured circuit parameters may be the individualized identifier for an integrated circuit chip. The random variation of the circuit parameter among the circuit elements serves as the fingerprint of the individual integrated circuit chip.

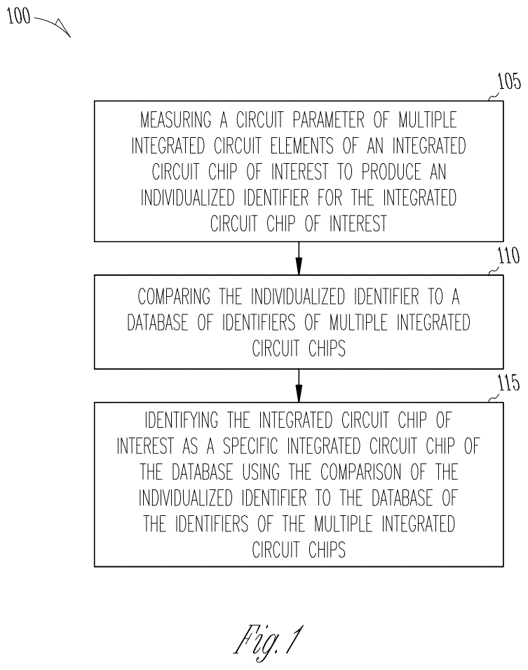

FIG. 1 is a flow diagram of an example of a method 100 of identifying integrated circuit chips without needing laser-scribing of the packaged chips or non-volatile memory data on the chips. The integrated circuit chip of interest to be identified includes many integrated circuit elements. At block 105, a circuit parameter of the integrated circuit elements is measured. The multiple circuit measurements are used to produce the individualized identifier for the integrated circuit chip.

At block 110, the individualized identifier obtained from the chip of interest is compared to a database of identifiers of multiple integrated circuit chips. The individualized identifiers for manufactured chips are read out from the chips at the time of manufacture and recorded in the database. The identifiers can be stored with manufacturing information in the database entries, such as one or more of a manufacturer lot number, manufacturing date, calibration details, configuration details, etc.

At block 115, the integrated circuit chip of interest is identified as a specific chip in the database by matching the read out identifier to an identifier in the database. The manufacturing information in the database associated with the specific chip can be read to provide traceability for the integrated circuit chip of interest.

The variations in the circuit parameter used for identification of the chips should be sufficient that the variations can be detected, and the variation in the circuit parameter between chips should be sufficient that any changes in the circuit parameter throughout the life of the chip does not confound the identifying of one chip from another. One approach is to use resistors as the circuit elements and the resistance as the circuit parameter of the identifier. An array of resistors can be fabricated on the chip using doped silicon, polysilicon layers, or other conductive materials. The resistances of the fabricated resistors are measured and read out to produce a data set of resistances as the identifier used to distinguish individual chips from each other. Other circuit elements can be used. In another example, an array of capacitors are the circuit elements, and the capacitance is used as the circuit parameter for the identifier. In still another example, an array of transistors are the circuit elements, and the threshold voltage of the transistors is used as the circuit parameter for the identifier. In a further example, the integrated circuit chips can include multiple ring oscillators as the circuit elements and the frequency of the ring oscillators is used as the circuit parameter for the identifier.

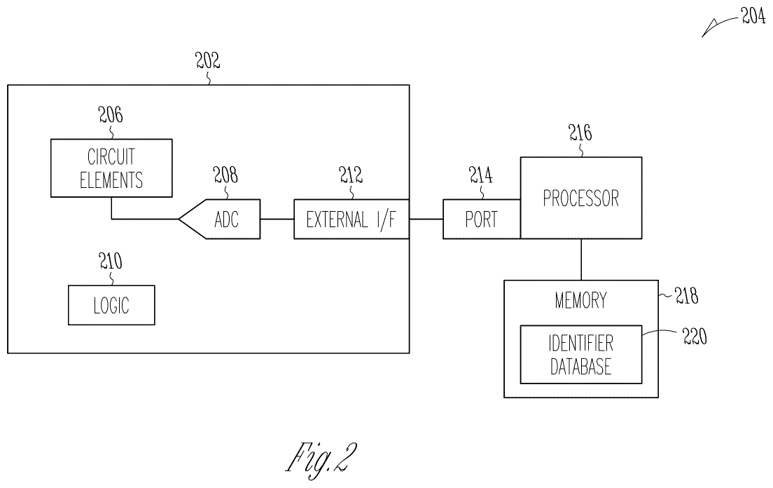

FIG. 2 is a block diagram of an integrated circuit chip 202 and an electronic device 204 to identify the integrated circuit chip 202 as a specific chip. The integrated circuit chip 202 includes an array of integrated circuit elements 206, an analog to digital converter (ADC) circuit 208, and logic circuitry 210. The logic circuitry 210 is configured to control timing of measurement circuits in the integrated circuit chip 202 and quantization of the measurements by the ADC circuit 208 to produce digital values representative of the measured circuit parameter of the integrated circuit elements 206. The logic circuitry 210 may also output the produced digital values to the external interface 212 as the individualized identifier of the integrated circuit chip 202.

The electronic device 204 includes a port 214 to receive the individualized identifier from the integrated circuit chip 202 and a processor circuit 216. The electronic device 204 may include a memory 218 to store a database 220 of identifiers of multiple integrated circuit chips. The processor circuit 216 can include a microprocessor, an application specific integrated circuit (ASIC), or other type of processor, interpreting or executing instructions included in software or firmware. The memory 218 is operatively coupled to the processor and may be integral to, or separate from, the processor circuit 216. In variations, the identifier database 220 is stored in memory in the internet cloud.

The processor circuit 216 is configured (e.g., by programming) to compare the individualized identifier from the integrated circuit chip 202 to the identifiers stored in the identifier database 220 and identify the integrated circuit chip of interest as a specific integrated circuit of the identifier database 220 by matching individualized identifiers. The identifier database 220 stores manufacturing information with the identifiers. For example, the identifier database 220 may be configured as a data structure indexed using the identifiers to find the manufacturing information for the integrated circuit chip 202. The processor may present the manufacturing information of the integrated circuit chip 202 to a user, such as by displaying the information.

Different approaches can be used to measure the circuit parameters of the integrated circuit elements 206 of the integrated circuit chip 202. For example, if the integrated circuit elements are resistors, some combination of voltage (or current) sources can be applied to the resistors and by measuring the resulting current (or voltage) the resistance can be derived from Ohm's Law. However, instability of the excitation sources (e.g., noise, variation in supply voltage, etc.), together with environmental factors (e.g., temperature) can affect the resistors and potentially compromise the underlying resistance measurements, which may impact the stability of the identifiers for the integrated circuit chip 202.

To improve stability of the identifiers, a ratio of resistances can be used as the circuit parameter used to produce the identifier. For example, the integrated circuit resistors can be fabricated using thin film deposition of the resistive material and photolithography etching can be used to pattern the resistors. A reference resistor can be fabricated that is a replica of the integrated circuit resistors. When an excitation current is applied to a resistor of the integrated circuit elements 206 the same excitation current is applied to the reference resistor. The ratio of the resistances is related to the ratio of the voltages induced on the resistors.

The voltage on the integrated resistors and the reference resistor may be measured using the ADC circuit 208. The ratio may then be calculated using the logic circuitry 210 or the processor circuit 216. In another example, the ADC circuit 208 is a ratio-metric ADC circuit. In a ratio-metric ADC circuit two voltages (or currents) are inputs to the ADC and the digital output is a ratio of the two input values without the ratio needing to be calculated in an additional step.

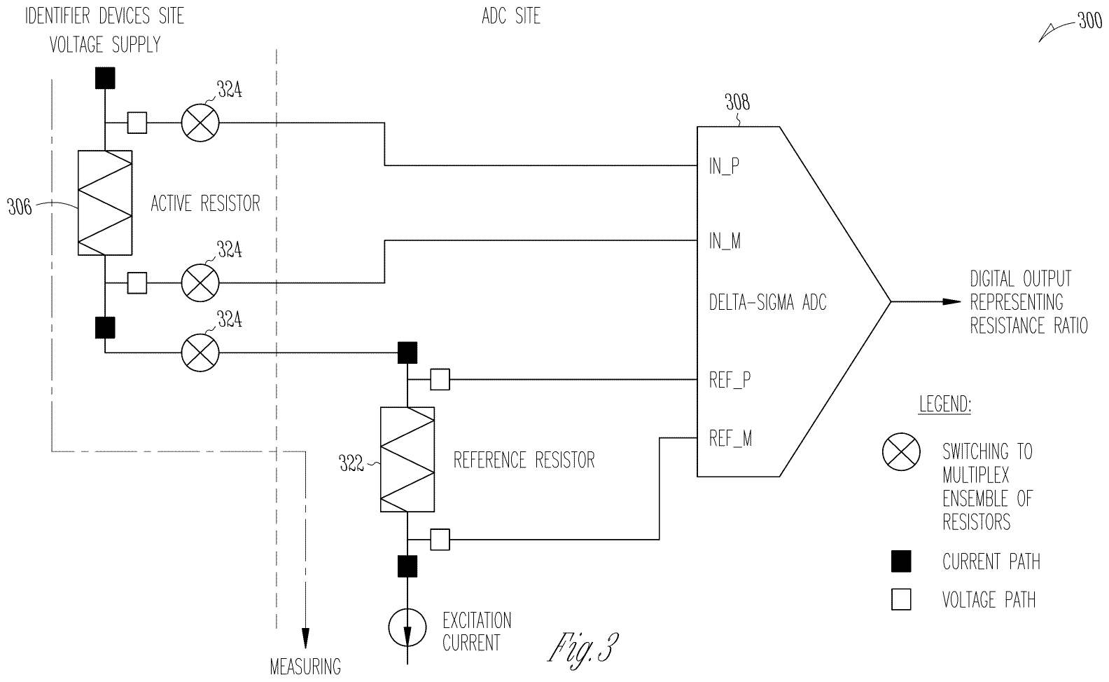

FIG. 3 is a circuit diagram of an example of a measurement circuit 300 to measure ratios of integrated circuit resistors 306 to a reference resistor 322. The integrated circuit resistors 306 are identical or nominally identical. The integrated circuit resistors 306 are nominally identical in that they are fabricated to have the same resistance within the tolerance (e.g., ±10%) of the manufacturing process. The reference resistor is identical or nominally identical to the integrated circuit resistors 306. The measurement circuit includes a ratio-metric ADC circuit 308. The ratio-metric ADC circuit 308 has two inputs labeled IN_P, IN_M and REF_P, REF_M. Switches 324 multiplex the resistors of the integrated circuit elements 206 in FIG. 2 onto the first input. The reference resistor 322 is connected in series to each of the integrated circuit resistors 306 in turn and an excitation current runs through both resistors. This allows the integrated circuit resistors 306 to be selectively measured without introducing measurement errors due to voltage drops in the switches or conductive interconnect. In some examples, the integrated circuit resistors 306 are arranged as a two-dimensional array of resistors having row and columns. The integrated circuit chip 202 may include a ratio-metric ADC circuit 308 for each column (or row) and the ratio-metric ADC circuit 308 produces the digital values for the resistors of that column (or row) of the two-dimensional array.

The output of the ratio-metric ADC circuit 308 is a digital value representing the ratio of the resistances at the inputs. The reference input of the ratio-metric ADC (REF_P, REF_M) is the voltage of the reference resistor and integrated circuit resistors are connected in turn to the signal input (IN_P, IN_M). The individualized identifier for the integrated circuit chip 202 may be the digital values for the ratios of the integrated resistors of the integrated circuit resistors 306 to the reference resistor 322, and the digital values are insensitive to the excitation current.

According to some examples, the integrated circuit elements 206 of the integrated circuit chip 202 includes temperature sensors. The temperature sensors can be resistance-temperature-detectors (RTDs). For RTDs, a change in temperature of the resistive element results in a change in the value of resistance of the resistive element. Similar to using the resistors as the integrated circuit elements, the resistance change of the RTDs can be detected by forcing a controlled current through the RTD, and then measuring the voltage across the resistor and the resistance derived through Ohm's Law. As the temperature changes, the resistance changes, and the measured voltage varies. From the changes in the measured voltage, the temperature can be inferred. Using a normal ADC to quantize the RTD voltage may produce results that vary depending on several circuit factors. Using the ratio-metric ADC approach in FIG. 3 makes the results insensitive to the circuit factors. The RTDs replace the integrated circuit resistors 306 in the FIG. 3 at the signal input, and a reference RTD replaces the reference resistor 322 at the reference input.

The reference RTD is a replica of the RTDs in the array of integrated circuit elements 206 and is fabricated to have the same geometry. The array of RTDs and the reference RTD are manufactured simultaneously under the same conditions to be identical or nominally identical. The reference RTD may be arranged at a known temperature, similar in nature to the “cold junction” of a thermocouple. The digital output of the ratio-metric ADC circuit 308 will reflect the ratio of the resistances of the RTDs of the array and the reference RTD. The individualized identifier for the integrated circuit chip 202 may be the digital values for the ratios of the resistances, and the digital values are insensitive to the excitation current.

If the RTD resistance is proportional to absolute temperature (a reasonable approximation for the RTD material over the range of temperatures in this application), then the RTD can be described as having a temperature coefficient of resistance (TCR). If the resistance is R0 at a temperature T0, a resistance R1 at a temperature T1, and with T1−T0=deltaT, then

$$R 1 = R 0 + deltaT * TCR * R 0 , or$$

$$R 1 / R 0 = 1 + deltaT * TCR .$$

When RTDs are used as thermometers or temperature sensors, then to the degree that the RTDs are identically constructed, the respective R0 values are the same for the reference RTD and the RTDs of the array. Therefore, the ratio of the resistances of the two RTDs measured using the ratio-metric ADC becomes 1+deltaT*TCR. It is to be noted that the result is insensitive to the nominal resistance of the RTD devices, including general manufacturing variations due to bulk material properties, thin film thickness, or lithographic imaging and etching perturbations. The digital value output by the ratio-metric ADC circuit 308 becomes responsive only to the difference in temperature between the measured RTDs, with magnitude of the digital value proportional to the TCR of the RTD material.

For high-accuracy temperature measurements it is generally necessary to calibrate individual RTDs even with well-controlled manufacturing. Inevitable variations in manufacturing (e.g., variations in film thickness and lithography) change the absolute resistance of the RTD, which introduces an offset in the estimated temperature from resistance. Variations in material composition change the TCR, which may lead to a sensitivity error or slope error for temperature versus resistance as the temperature being measured changes. Measurements of the RTDs under known temperature conditions allows extraction of the desired correction factors.

In a realistic semiconductor manufacturing scenario, it is likely that the material properties of the reference RTD and the array RTDs on a particular chip will be extremely similar. In that case, the TCR values for the pairs being measured using the ratio-metric ADCs will be nearly the same or nominally identical, and if the RTDs are both at the same temperatures, the measured ratios will be essentially unaffected by the value of that temperature. The result is that the manufacturing variations will only introduce offsets in the ratios measured using the ratio-metric ADC. The individualized identifier measured will be insensitive to the temperature at which it is read. This makes the requirements on the measurement system much simpler. The temperature of the chip does not to be precisely controlled to read the individualized identifier for the chip. The measurement system merely ensures that the power dissipated during the measurement avoids introducing significant temperature gradients in the integrated circuit chips. While the individual identifiers or fingerprints of two different chips have some common characteristics, they will nevertheless be distinctly different.

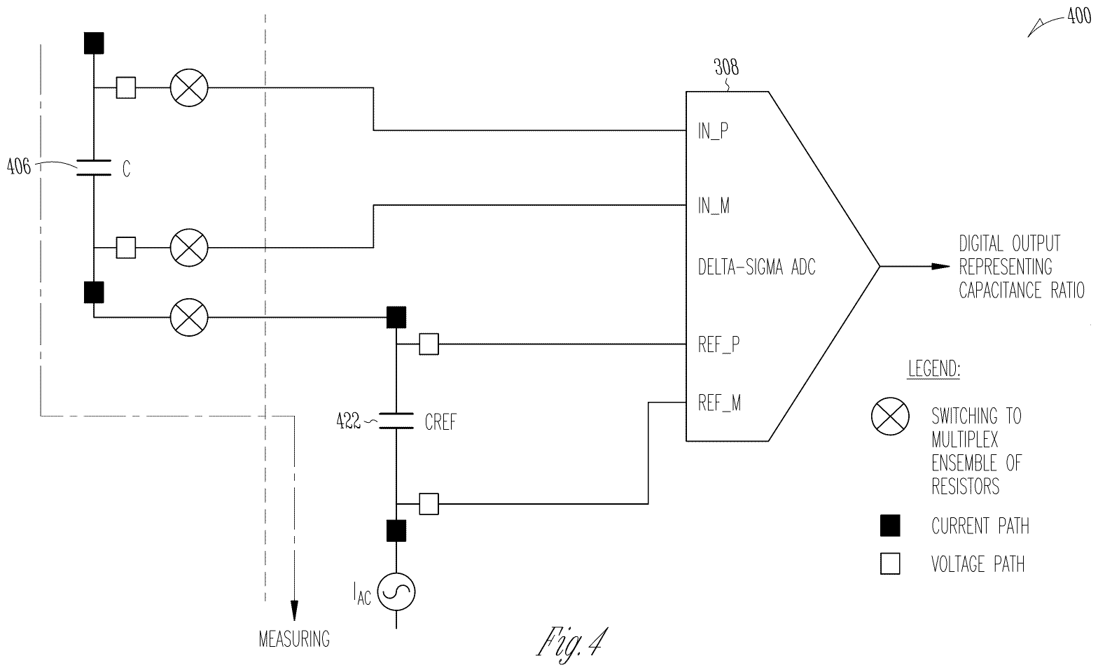

As explained previously herein, other circuit elements can be used than resistive devices for the integrated circuit elements that produce the individualized identifiers. FIG. 4 is an example of using integrated capacitors. The integrated circuit elements 206 in the chip in FIG. 2 are capacitors C. The capacitors may be unit capacitors of the same size and may be identical or nominally identical. A reference capacitor C_{REF} is a replica of the capacitors in the array. An alternating current (AC) excitation current (I_{AC}) is passed through an array capacitor C and the reference capacitor C_{REF} connected in series, and the result change in voltage (ΔV) is proportional to the ratio of current and capacitance. The array capacitor C is connected to the signal input of the ratio-metric ADC circuit 308 and the reference capacitor is connected to the reference input of the ratio-metric ADC circuit 308. The digital value output by the ratio-metric ADC circuit 308 is the ratio of the voltages on the inputs. These digital vales can be used to produce the individualized identifier of the integrated circuit chip.

The circuits and methods described include techniques for uniquely identifying integrated circuits without laser scribing an identifier on them or adding an identifier to a non-voltage memory. The techniques take into account that every integrated circuit chip will have inherent manufacturing variations from one chip to the next even though the chips are manufactured to be identical. These variations are used to produce a uniquely identifying fingerprint for integrated circuit chips that provides traceability of individual chips in the field after they leave manufacturing.

### Additional Description and Aspects

A first Aspect (Aspect 1) includes subject matter (such as a method of identifying individual integrated circuits) comprising measuring a circuit parameter of multiple integrated circuit elements of an integrated circuit chip of interest to produce an individualized identifier for the integrated circuit chip of interest using multiple measurements of the circuit parameter; comparing the individualized identifier to an identifier database including identifiers of multiple integrated circuit chips; and identifying the integrated circuit chip of interest as a specific integrated circuit chip of the identifier database using the comparing of the individualized identifier to the identifier database.

In Aspect 2, the subject matter of Aspect 1 optionally includes measuring resistance of multiple nominally identical integrated circuit resistors of the integrated circuit chip of interest; measuring resistance of multiple nominally identical integrated circuit resistors of the integrated circuit chip of interest; and calculating a ratio including the measured resistance of the multiple identical integrated circuit resistors and the measured resistance of the reference integrated circuit resistor as the circuit parameter to produce the individualized identifier for the integrated circuit chip of interest.

In Aspect 3, the subject matter of one or both of Aspects 1 and 2 optionally includes measuring capacitance of multiple nominally identical capacitors of the integrated circuit chip of interest; measuring capacitance of a reference capacitor of the integrated circuit chip of interest; and calculating a ratio including the measured capacitance of the multiple identical capacitors and the measured capacitance of the reference capacitor as the circuit parameter to produce the individualized identifier for the integrated circuit chip of interest.

In Aspect 4, the subject matter of one or any combination of Aspects 1-3 optionally includes measuring a temperature coefficient of resistance (TCR) of multiple nominally identical resistance-temperature-detectors (RTDs) of the integrated circuit chip of interest; measuring a TCR of a reference RTD of the integrated circuit chip of interest; and calculating a ratio including the measured TCR for the multiple identical RTDs and the TCR for the reference RTD as the circuit parameter to produce the individualized identifier for the integrated circuit chip of interest.

In Aspect 5, the subject matter of one or any combination of Aspects 1-4 optionally includes determining digital values of a ratio including a voltage of the multiple integrated circuit elements and a voltage of a reference integrated circuit element; and producing the individualized identifier for the integrated circuit chip of interest using the determined digital values.

In Aspect 6, the subject matter of Example 5 optionally includes determining the digital values of the ratio using a ratio-metric analog-to-digital converter (ADC) circuit.

In Aspect 7, the subject matter of one or any combination of Examples 1-6 optionally includes storing, in the identifier database, database entries including the identifiers of the multiple integrated circuits stored in association with manufacturing information of the multiple integrated circuits; and determining the manufacturing information of the specific integrated circuit according to the comparing of the individualized identifier for the integrated circuit chip of interest to the identifier database.

In Aspect 8, the subject matter of one or any combination of Examples 1-7 optionally includes measuring the circuit parameter of multiple identical integrated circuit elements fabricated in a two-dimensional array on the integrated circuit chip of interest.

Aspect 9 includes subject matter (such as an integrated circuit chip) or can optionally be combined with one or any combination of Aspects 1-8 to include such subject matter, comprising multiple integrated circuit elements; an ADC circuit; and logic circuitry. The logic circuitry is configured to produce, using the ADC circuit, digital values representative of a circuit parameter of the multiple integrated circuit elements; and output an individualized identifier of the integrated circuit chip that includes the produced digital values.

In Aspect 10, the subject matter of Aspect 9 optionally includes a reference integrated circuit element; and logic circuitry configured to produce digital values representative of a ratio including the circuit parameter of the multiple integrated circuit elements and a circuit parameter of the reference integrated circuit element. In Aspect 11, the subject matter of Aspect 10 optionally includes multiple integrated circuit elements that are multiple nominally identical integrated circuit resistors, a reference integrated circuit element that is a reference integrated circuit resistor, and logic circuitry configured to produce digital values representative of a ratio including a resistance of the multiple nominally identical integrated circuit resistors and a resistance of the reference integrated circuit resistor.

In Aspect 12, the subject matter of Aspect 10 optionally includes multiple integrated circuit elements that are multiple nominally identical capacitors, a reference integrated circuit element that is a reference capacitor, and logic circuitry configured to produce digital values representative of a ratio including a capacitance of the multiple nominally identical capacitors and a capacitance of the reference capacitor.

In Aspect 13, the subject matter of Aspect 10 optionally includes multiple integrated circuit elements are multiple nominally identical resistance-temperature-detectors (RTDs), a reference integrated circuit element that is a reference RTD, and logic circuitry configured to produce digital values representative of a ratio including a temperature coefficient of resistance (TCR) of the multiple nominally identical RTDs and a TCR of the reference RTD.

In Aspect 14, the subject matter of one or any combination of Examples 10-13 optionally includes an ADC circuit that is a ratio-metric ADC circuit, and logic circuitry configured to produce a voltage on the multiple integrated circuit elements, produce a voltage on the reference integrated circuit element, and produce digital values representative of a ratio including the voltage of a reference integrated circuit element and the voltage of an integrated circuit element of the multiple integrated circuit elements.

In Aspect 15, the subject matter of one or any combination of Examples 9-14 optionally includes multiple integrated circuit elements that are arranged in a two-dimensional array of the integrated circuit elements on the integrated circuit chip; multiple ratio-metric ADC circuits included in the integrated circuit chip, and each ratio-metric ADC circuit produces the digital values for one column or row of the two-dimensional array of the integrated circuit elements.

In Aspect 16, the subject matter of one or any combination of Aspects 9-15 optionally includes the integrated circuit chip excluding a memory circuit.

Aspect 17 includes subject matter (such as electronic device) or can optionally be combined with one or any combination of Aspects 1-16 to include such subject matter, comprising a memory, a port, and a processor operatively coupled to the memory and the port. The memory is configured to store n identifier database including identifiers of multiple integrated circuit chips. The identifiers include measurements of a circuit parameter of multiple integrated circuit elements of each of the multiple integrated circuit chips. The port is configured to receive an individualized identifier for an integrated circuit chip of interest, wherein the individualized identifier includes measurements of a circuit parameter of multiple integrated circuit elements of the integrated circuit chip of interest. The processor is configured to compare the individualized identifier to identifiers of the identifier database; identify the integrated circuit chip of interest as a specific integrated circuit of the identifier database using the comparison; and present manufacturing information of the integrated circuit chip of interest according to the comparison of the individualized identifier to the identifier database.

In Aspect 18, the subject matter of Aspect 17 optionally includes an identifier database that includes measured resistance ratios of the multiple integrated circuit chips, and the resistance ratios are ratios that include resistance of multiple integrated circuit resistors of an integrated circuit chip and resistance of a reference integrated circuit resistor of the integrated circuit chip. The processor is optionally configured to compare, as the individualized identifier, measured resistance ratios of the of the integrated circuit of interest to the measured resistance ratios of the identifier database to identify the specific integrated circuit chip of the identifier database.

In Aspect 19, the subject matter of one or both of Aspects 17 and 18 optionally includes an identifier database that includes measured capacitance ratios of the multiple integrated circuit chips, and the capacitance ratios are ratios that include capacitance of multiple capacitors of an integrated circuit chip and capacitance of a reference capacitor of the integrated circuit chip. The processor is optionally configured to compare, as the individualized identifier, measured capacitance ratios of the of the integrated circuit of interest to the measured capacitance ratios of the identifier database to identify the specific integrated circuit chip of the identifier database.

In Aspect 20, the subject matter of one or any combination of Aspects 17-19 optionally includes an identifier database that includes measured temperature coefficient of resistance (TCR) ratios of the multiple integrated circuit chips, and the TCR ratios are ratios that include the TCR of multiple resistance-temperature-detectors (RTDs) of an integrated circuit chip and a TCR of a reference RTD of the integrated circuit chip. The processor is optionally configured to compare, as the individualized identifier, measured TCR ratios of the of the integrated circuit of interest to the measured TCR ratios of the identifier database to identify the specific integrated circuit chip of the identifier database.

These non-limiting Aspects can be combined in any permutation or combination. The above detailed description includes references to the accompanying drawings, which form a part of the detailed description. The drawings show, by way of illustration, specific embodiments in which the invention can be practiced. These embodiments are also referred to herein as “examples.” All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects. Method examples described herein can be machine or computer-implemented at least in part.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment. The scope of the invention should be determined with reference to the appended claims, along with the full scope of equivalents to which such claims are entitled.

What is claimed is:

1. A method comprising:
measuring a circuit parameter of multiple integrated circuit elements of an integrated circuit chip of interest to produce an individualized identifier for the integrated circuit chip of interest using multiple measurements of the circuit parameter;
comparing the individualized identifier to an identifier database including identifiers of multiple integrated circuit chips; and
identifying the integrated circuit chip of interest as a specific integrated circuit chip of the identifier database using the comparing of the individualized identifier to the identifier database.

2. The method of claim 1, wherein the measuring the circuit parameter includes:
measuring resistance of multiple nominally identical integrated circuit resistors of the integrated circuit chip of interest;
measuring resistance of a reference integrated circuit resistor of the integrated circuit chip of interest; and
calculating a ratio including the measured resistance of the multiple identical integrated circuit resistors and the measured resistance of the reference integrated circuit resistor as the circuit parameter to produce the individualized identifier for the integrated circuit chip of interest.

3. The method of claim 1, wherein the measuring the circuit parameter includes:
measuring capacitance of multiple nominally identical capacitors of the integrated circuit chip of interest;
measuring capacitance of a reference capacitor of the integrated circuit chip of interest; and
calculating a ratio including the measured capacitance of the multiple identical capacitors and the measured capacitance of the reference capacitor as the circuit parameter to produce the individualized identifier for the integrated circuit chip of interest.

4. The method of claim 1, wherein the measuring the circuit parameter includes:
measuring a temperature coefficient of resistance (TCR) of multiple nominally identical resistance-temperature-detectors (RTDs) of the integrated circuit chip of interest;
measuring a TCR of a reference RTD of the integrated circuit chip of interest; and
calculating a ratio including the measured TCR for the multiple identical RTDs and the TCR for the reference RTD as the circuit parameter to produce the individualized identifier for the integrated circuit chip of interest.

5. The method of claim 1, wherein the measuring the circuit parameter includes:
determining digital values of a ratio including a voltage of the multiple integrated circuit elements and a voltage of a reference integrated circuit element; and
producing the individualized identifier for the integrated circuit chip of interest using the determined digital values.

6. The method of claim 5, wherein the determining the digital values of the ratio includes determining the digital values of the ratio using a ratio-metric analog-to-digital converter (ADC) circuit.

7. The method of claim 1, including:
storing, in the identifier database, database entries including the identifiers of the multiple integrated circuits stored in association with manufacturing information of the multiple integrated circuits; and
determining the manufacturing information of the specific integrated circuit according to the comparing of the individualized identifier for the integrated circuit chip of interest to the identifier database.

8. The method of claim 1, wherein the measuring the circuit parameter includes measuring the circuit parameter of multiple identical integrated circuit elements fabricated in a two-dimensional array on the integrated circuit chip of interest.

9. An integrated circuit chip comprising:
multiple integrated circuit elements;
an analog-to-digital converter (ADC) circuit; and
logic circuitry configured to:
produce, using the ADC circuit, digital values representative of a circuit parameter of the multiple integrated circuit elements; and
output an individualized identifier of the integrated circuit chip that includes the produced digital values.

10. The integrated circuit chip of claim 9, including:
a reference integrated circuit element; and
wherein the logic circuitry is configured to produce digital values representative of a ratio including the circuit parameter of the multiple integrated circuit elements and a circuit parameter of the reference integrated circuit element.

11. The integrated circuit chip of claim 10,
wherein the multiple integrated circuit elements are multiple nominally identical integrated circuit resistors and the reference integrated circuit element is a reference integrated circuit resistor; and
wherein the logic circuitry is configured to produce digital values representative of a ratio including a resistance of the multiple nominally identical integrated circuit resistors and a resistance of the reference integrated circuit resistor.

12. The integrated circuit chip of claim 10,
wherein the multiple integrated circuit elements are multiple nominally identical capacitors and the reference integrated circuit element is a reference capacitor; and
wherein the logic circuitry is configured to produce digital values representative of a ratio including a capacitance of the multiple nominally identical capacitors and a capacitance of the reference capacitor.

13. The integrated circuit chip of claim 10,
wherein the multiple integrated circuit elements are multiple nominally identical resistance-temperature-detectors (RTDs) and the reference integrated circuit element is a reference RTD; and
wherein the logic circuitry is configured to produce digital values representative of a ratio including a temperature coefficient of resistance (TCR) of the multiple nominally identical RTDs and a TCR of the reference RTD.

14. The integrated circuit chip of claim 10, including:
wherein the ADC circuit is a ratio-metric ADC circuit and the logic circuitry is configured to:
produce a voltage on the multiple integrated circuit elements;
produce a voltage on the reference integrated circuit element; and
produce digital values representative of a ratio including the voltage of a reference integrated circuit element and the voltage of an integrated circuit element of the multiple integrated circuit elements.

15. The integrated circuit chip of claim 9,
wherein the multiple integrated circuit elements are arranged in a two-dimensional array of the integrated circuit elements on the integrated circuit chip;
wherein the ADC circuit is one of multiple ratio-metric ADC circuits included in the integrated circuit chip; and
wherein each ratio-metric ADC circuit produces the digital values for one column or row of the two-dimensional array of the integrated circuit elements.

16. The integrated circuit of claim 9, wherein the integrated circuit chip excludes a memory circuit.

17. An electronic device comprising:
a memory configured to store an identifier database including identifiers of multiple integrated circuit chips, wherein the identifiers include measurements of a circuit parameter of multiple integrated circuit elements of each of the multiple integrated circuit chips;
a port to receive an individualized identifier for an integrated circuit chip of interest, wherein the individualized identifier includes measurements of a circuit parameter of multiple integrated circuit elements of the integrated circuit chip of interest; and
a processor operatively coupled to the memory and the port, wherein the processor is configured to:
compare the individualized identifier to identifiers of the identifier database;
identify the integrated circuit chip of interest as a specific integrated circuit of the identifier database using the comparison; and
present manufacturing information of the integrated circuit chip of interest according to the comparison of the individualized identifier to the identifier database.

18. The electronic device of claim 17,
wherein the identifier database includes measured resistance ratios of the multiple integrated circuit chips, wherein the resistance ratios are ratios that include resistance of multiple integrated circuit resistors of an integrated circuit chip and resistance of a reference integrated circuit resistor of the integrated circuit chip; and
wherein the processor is configured to compare, as the individualized identifier, measured resistance ratios of the of the integrated circuit of interest to the measured resistance ratios of the identifier database to identify the specific integrated circuit chip of the identifier database.

19. The electronic device of claim 17,
wherein the identifier database includes measured capacitance ratios of the multiple integrated circuit chips, wherein the capacitance ratios are ratios that include capacitance of multiple capacitors of an integrated circuit chip and capacitance of a reference capacitor of the integrated circuit chip; and
wherein the processor is configured to compare, as the individualized identifier, measured capacitance ratios of the of the integrated circuit of interest to the measured capacitance ratios of the identifier database to identify the specific integrated circuit chip of the identifier database.

20. The electronic device of claim 17,
wherein the identifier database includes measured temperature coefficient of resistance (TCR) ratios of the multiple integrated circuit chips, wherein the TCR ratios are ratios that include the TCR of multiple resistance-temperature-detectors (RTDs) of an integrated circuit chip and a TCR of a reference RTD of the integrated circuit chip; and
wherein the processor is configured to compare, as the individualized identifier, measured TCR ratios of the of the integrated circuit of interest to the measured TCR ratios of the identifier database to identify the specific integrated circuit chip of the identifier database.
